(19) United States
(12) Patent Application Publication
(10) Pub. No.: US 2010/0285415 A1
(43) Pub. Date: Nov. 11, 2010

(54) Burner Element and Burner Having Aluminum Oxide Coating and Method for Coating a Burner Element

(76) Inventors: Andreas Böttcher, Ratingen (DE); Claus Krusch, Mulheim an der Ruhr (DE); Werner Stamm, Mulheim an der Ruhr (DE); Ulrich Wörz, Orlando, FL (US)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 12/744,195

(22) PCT Filed: Mar. 3, 2008
(86) PCT No.: PCT/EP2008/052556

§ 371 Date: May 21, 2010

(30) Foreign Application Priority Data
Nov. 23, 2007 (DE) 10 2007 056 805.5

(51) Int. Cl. F23D 11/36; C23C 16/40

(52) U.S. Cl. 431/159; 427/255.28

(57) ABSTRACT

A burner element is provided. The burner element includes a surface that potentially comes into contact with a fuel. The surface potentially coming into contact with the fuel has a coating including aluminum oxide. A burner including the burner element is also provided. Further, a method for coating a surface of a burner element potentially coming into contact with a fuel is described, wherein the surface potentially coming into contact with the fuel is coated with aluminum oxide.

### CROSS REFERENCE TO RELATED APPLICATIONS

This application is the US National Stage of International Application No. PCT/EP2008/052556, filed Mar. 3, 2008 and claims the benefit thereof. The International Application claims the benefits of German application No. 10 2007 056 805.5 DE filed Nov. 23, 2007. All of the applications are incorporated by reference herein in their entirety.

### FIELD OF INVENTION

The present invention relates to a burner element and a burner having an aluminum oxide coating. In addition, the present invention relates to a process for coating a burner element.

### BACKGROUND OF INVENTION

Specific parts of a burner typically come into contact with fuel in their interior. Iron sulfide deposits may be formed in the interior of the burner owing to the chemical reaction between sulfur compounds (H₂S) present in the fuel and the base material of the burner. The base material of the burner is typically steel, for example 16Mo3 steel. The iron sulfide deposits which are formed in the interior of the burner may spall and partially block the bores through which the fuel is injected into a combustion chamber. The bores, through which the fuel is injected into the combustion chamber, typically have a diameter of 1.5 mm. Blockage of these bores results in nonuniform combustion, as a result of which the emission values of the affected burner, in particular, deteriorate considerably. In this case, the availability of the affected burner or of the associated combustion chamber is impaired.

To date, the problem of possible blockage of the bores as a result of spalling iron sulfide deposits has been solved either by cleaning the burner or by the installation of a new burner. However, cleaning takes a long time. In such cases, a complete set of new burners therefore generally has to be installed, but this is very expensive. Although the difficulties described arise only on machines which are operated with preheating, these machines are increasingly being used. Therefore, high additional costs are to be expected owing to the possible formation of iron sulfide deposits.

### SUMMARY OF INVENTION

Therefore, it is an object of the present invention to provide an advantageous burner element. A further object of the present invention is to provide an advantageous burner. In addition, it is an object of the present invention to provide an advantageous process for coating a surface of a burner element which potentially comes into contact with a fuel.

The first object is achieved by means of a burner element as claimed in the claims. The second object is achieved by means of a burner as claimed in the claims. The third object is achieved by means of a process as claimed in the claims. The dependent claims contain further, advantageous refinements of the invention.

The burner element according to the invention comprises a surface which potentially comes into contact with a fuel. The surface which potentially comes into contact with the fuel has an aluminum oxide-containing coating. A protective layer is produced between the material of the burner element and the aggressive sulfur compounds in the fuel by coating the burner element with an aluminum oxide layer. This prevents the formation of particles or possibly spalling deposits in the burner element. This prevents possible blockage of the bores through which the fuel is injected into a combustion chamber, and thus makes it easier to comply with the emission limits. Furthermore, costs for cleaning, which may be required, or for the installation of a new burner can be saved with the aid of the burner element according to the invention.

The aluminum oxide-containing coating of the burner element according to the invention can comprise, for example, α-Al₂O₃. With preference, the coating can comprise an aluminum-rich first layer and an aluminum oxide-containing second layer arranged above the first layer. The aluminum oxide-containing coating can be an aluminum oxide layer. The coating can advantageously have a layer thickness of 50 μm to 100 μm.

The burner element according to the invention can comprise steel as base material, for example 16Mo3 steel. The burner element according to the invention may be a fuel feed line or a fuel distributor, for example a fuel gas feed line, a fuel gas premix feed line or a fuel gas diffusion feed line.

The burner according to the invention comprises a burner element according to the invention having the above-described features. The burner according to the invention may be, for example, a pilot burner. A pilot burner, in particular, can have small nozzle bores having a diameter of between 0.5 mm and 2 min, preferably 1 mm. These bores are effectively protected against possible blockage by the coating, according to the invention, of the burner element with aluminum oxide. Overall, the burner according to the invention has the same advantages as the burner element according to the invention.

Both the burner according to the invention and the burner element according to the invention can be used, for example, in a combustion chamber, preferably in a combustion chamber of a gas turbine.

Within the context of the process according to the invention for coating a surface of a burner element which potentially comes into contact with a fuel, the surface which potentially comes into contact with the fuel is coated with an aluminum oxide-comprising layer. As a result of the coating, the burner material is effectively protected against the aggressive sulfur compounds in the fuel and against possible formation of iron sulfide deposits.

The aluminum oxide can be applied to the surface by chemical vapor deposition (CVD). Coating processes of this type can be carried out at very low cost. In principle, however, the aluminum oxide layer can also be applied by a different diffusion process. By way of example, the surface can be enriched with aluminum at a temperature between 1000° C. and 1100° C. within the scope of the chemical vapor deposition. The surface is advantageously enriched with aluminum at a temperature of 1050° C. In addition, the surface can be enriched with aluminum over a period of time of between 3 and 5 hours, advantageously over a period of time of 4 hours, within the scope of the chemical vapor deposition. Furthermore, the surface can be aged at a temperature between 800° C. and 900° C., preferably at 850° C., after it has been enriched with aluminum, within the scope of the chemical vapor deposition. In addition, the surface can be aged over a period of time of between 1 and 3 hours, preferably over a period of time of 2 hours, after it has been enriched with aluminum, within the scope of the chemical vapor deposition.

The enrichment with aluminum and the subsequent aging produce an aluminum oxide layer on the surface. This layer is extremely stable and non-reactive. By way of example, a coating having a thickness of 50 μm to 100 μm can be produced with the aid of the process according to the invention. This relatively small layer thickness means that thermal spalling should not be expected. This process also ensures that the surface of the burner element, which potentially comes into contact with a fuel and may be, for example, the interior of a burner, is covered completely with a protective layer. Overall, the process according to the invention makes it possible to coat the surface of a burner element or of a burner at low cost. The coating additionally improves the emission values of the burner.

### BRIEF DESCRIPTION OF THE DRAWINGS

Further properties, features and advantages of the present invention are described in more detail below on the basis of an exemplary embodiment, with reference to the accompanying figures.

FIG. 1 shows the dependence of the CO emission values of a conventional burner on the operating time.

FIG. 2 schematically shows a section through an HR3B-type burner capable of mixed operation.

FIG. 3 schematically shows a section through part of a burner element according to the invention.

FIG. 4 schematically shows a section through part of a burner element according to the invention.

FIG. 5 shows, by way of example, a partial longitudinal section through a gas turbine 100.

FIG. 6 schematically shows a combustion chamber of a gas turbine.

FIG. 7 shows a perspective view of a rotor blade or guide vane of a turbomachine, which extends along a longitudinal axis.

### DETAILED DESCRIPTION OF INVENTION

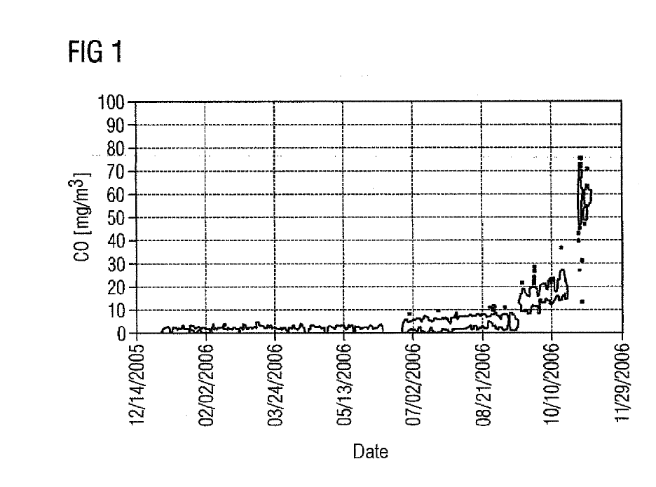

An exemplary embodiment of the present invention is explained in more detail below with reference to FIGS. 1 to 7.

FIG. 1 shows the dependence of the CO emission values of a conventional burner on the x-axis of the graph shown in FIG. 1. The CO emission values measured in each case are plotted in milligrams per cubic meter on the y-axis.

The graph shows that, for the relevant burner, the CO emission values in the time between mid-December 2005 and mid-June 2006 were below 5 mg/m³. In the time between mid-June 2006 and mid-September 2006, the CO emission values rose continuously, but were predominantly below 10 mg/m³. In the period of time between mid-September 2006 and the start of November 2006, the CO emission values rose more sharply than between mid-June 2006 and mid-September 2006, and in this period of time were predominantly between 10 mg/m³ and 30 mg/m³. CO emission values of predominantly between 40 mg/m³ and 80 mg/m³ were then measured between the start of November 2006 and mid-November 2006.

The measurement illustrated in FIG. 1 shows that increasing blockage of the burner resulting from the formation of iron sulfide deposits is accompanied by a considerable deterioration in the CO emission values. The burner used by way of example is a burner of a gas turbine.

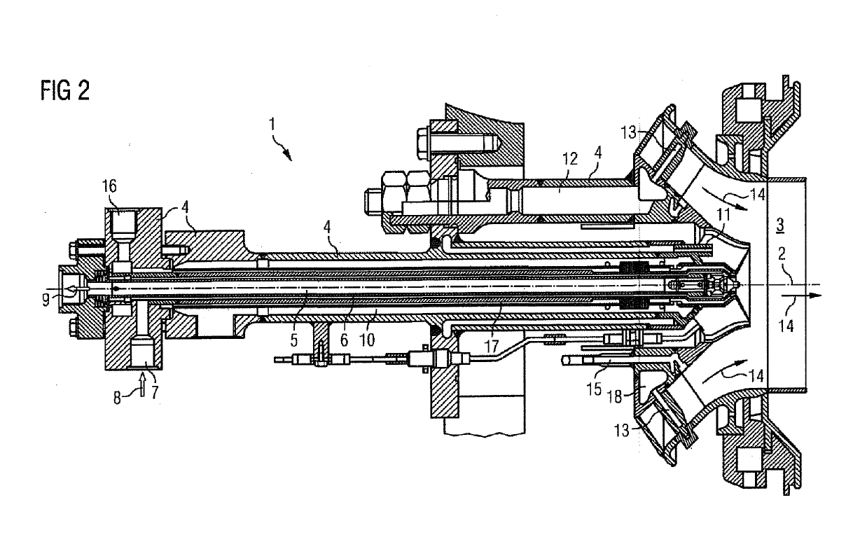

The design of a burner, as may be used, for example, in a gas turbine, is explained in more detail below with reference to FIG. 2. FIG. 2 schematically shows a section through a burner 1 according to the invention. The burner 1 is connected to a combustion chamber 3. The mid-axis of the burner 1 is denoted by reference numeral 2.

The burner 1 comprises a housing 4. A fuel oil return line 5 is arranged along the mid-axis 2 inside the housing 4. A fuel oil inflow line 6 is arranged concentrically around the fuel oil return line 5 and likewise runs along the mid-axis 2. In this case, there may also be the operating time. The respective date of the CO emission measurement is plotted on a plurality of fuel oil inflow lines 6 arranged concentrically around the fuel oil return line 5. On the side facing away from the combustion chamber 3, the fuel oil inflow line 6 is connected to a connection pipe 7, which may be connected to a fuel oil supply. The direction in which the fuel oil flows is indicated by the arrows 8 and 9. The fuel oil can initially flow through the connection pipe 7 into the fuel oil inflow line 6. The fuel oil can flow through this fuel oil inflow line 6, parallel to the mid-axis 2, toward the combustion chamber 3 and be injected into the combustion chamber 3. Excess fuel oil can flow away from the combustion chamber 3 in the direction of the arrow 9, parallel to the mid-axis 2, through the fuel oil return line 5.

One or more water lines 17 are arranged along the mid-axis 2 radially outside the fuel oil return line 5 and the fuel oil inflow line 6 with respect to the mid-axis 2. The water line or the water lines 17 is or are connected to a water inflow 16 on that side of the burner 1 which faces away from the combustion chamber 3.

A fuel gas diffusion line 10 is arranged concentrically around the fuel oil return line 5, the fuel oil inflow line 6 and the water lines 17. The fuel gas can be transferred in the fuel gas diffusion line 10 to fuel nozzles 11. The fuel nozzles 11 are likewise arranged concentrically around the mid-axis 2 and make it possible for the fuel to be injected into the combustion chamber 3.

A fuel gas premix feed line 12 is arranged radially outside the fuel gas diffusion line 10 with respect to the mid-axis 2, and fuel gas can be conducted through this feed line to further fuel nozzles 13 via a ring distributor 18 arranged annularly around the mid-axis 2. The fuel can be injected into the combustion chamber 3 through the fuel nozzles 13. The direction in which the fuel/air mixture flows in the combustion chamber 3 is denoted by arrows 14.

The inner surfaces of the fuel gas diffusion line 10, the fuel gas premix feed line 12 and the ring distributor 18 are in direct contact with the fuel gas flowing through them. The chemical reaction between sulfur compounds present in the fuel gas and the base material of these components may result in the formation of iron sulfide deposits on the inner surfaces of these components. These deposits may spall and partially block the fuel nozzles 11, 13.

In the present exemplary embodiment, the base material of the components described, i.e. in particular the fuel gas diffusion line 10, the fuel gas premix feed line 12 and the ring distributor 18, is 16Mo3 steel. The base material may also be a different material, for example a different steel grade. In order to prevent the formation of iron sulfide deposits on the inner surfaces of the fuel gas diffusion line 10, the fuel gas premix feed line 12 and the ring distributor 18, the inner surfaces of said components are covered with an aluminum oxide layer, preferably α-Al₂O₃. A protective layer is thereby produced between the base material and the aggressive sulfur compounds in the fuel.

The aluminum oxide layer is applied by a diffusion process, in particular by chemical vapor deposition (CVD). The coating process is broken down into two working steps. In the first step, the surface is enriched with aluminum at 1050° C. over the course of 4 hours by means of CVD. In the second step, the components are aged in a furnace at 850° C. over the course of two hours. This produces the aluminum oxide layer, which is extremely stable and non-reactive.

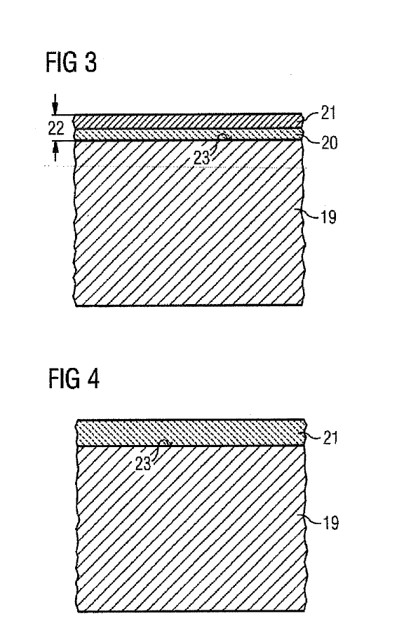

The coating produced by the described process is shown schematically in FIG. 3. FIG. 3 shows a section through part of a burner element according to the invention, where this part may be, for example, the fuel gas diffusion line 10, the fuel gas premix feed line 12 or the ring distributor 18 of the burner 1 according to the invention. Reference numeral 19 denotes the base material of the corresponding burner element 10, 12, 18. In the present exemplary embodiment, the base material 19 is 16Mo3 steel. An aluminum-containing aluminum-rich zone 20 is located on the inner surface 23 of the burner element 10, 12, 18. An aluminum oxide layer 21, which, in the present exemplary embodiment, is an α-Al₂O₃ layer, is located on this aluminum-rich zone 20. In this context, a indicates that this involves the aluminum oxide modification with a rhombohedral lattice structure. α-Al₂O₃ is also known as corundum and sapphire.

In the present exemplary embodiment, the thickness of the coating 22, consisting of the aluminum-rich zone 20 and the aluminum oxide layer 21, is between 50 μm and 100 μm.

FIG. 4 shows an alternative coating. FIG. 4 schematically shows a section through part of a burner element according to the invention. In contrast to FIG. 3, in FIG. 4 an aluminum oxide layer 21 has been applied directly to the inner surface 23 of the burner element 10, 12, 18, the base material 19 of which is 16Mo3 steel.

The coating of the inner surfaces of burner elements which potentially come into contact with fuel with an aluminum oxide layer prevents the formation of iron sulfide deposits and thus the formation of particles in the burner, which could result in blockage of the fuel nozzles.

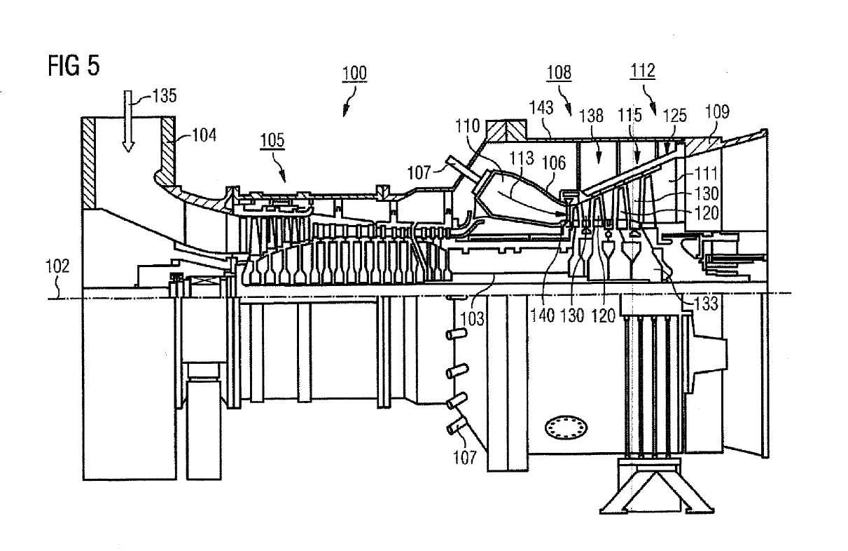

FIG. 5 shows, by way of example, a partial longitudinal section through a gas turbine 100.

In the interior, the gas turbine 100 has a rotor 103 with a shaft 101 which is mounted such that it can rotate about an axis of rotation 102 and is also referred to as the turbine rotor.

An intake housing 104, a compressor 105, a, for example, toroidal combustion chamber 110, in particular an annular combustion chamber, with a plurality of coaxially arranged burners 107, a turbine 108 and the exhaust-gas housing 109 follow one another along the rotor 103.

The annular combustion chamber 110 is in communication with a, for example, annular hot-gas passage 111, where, by way of example, four successive turbine stages 112 form the turbine 108.

Each turbine stage 112 is formed, for example, from two blade or vane rings. As seen in the direction of flow of a working medium 113, in the hot-gas passage 111 a row of guide vanes 115 is followed by a row 125 formed from rotor blades 120.

The guide vanes 130 are secured to an inner housing 138 of a stator 143, whereas the rotor blades 120 of a row 125 are fitted to the rotor 103 for example by means of a turbine disk 133.

A generator (not shown) is coupled to the rotor 103.

While the gas turbine 100 is operating, the compressor 105 sucks in air 135 through the intake housing 104 and compresses it. The compressed air provided at the turbine-side end of the compressor 105 is passed to the burners 107, where it is mixed with a fuel. The mix is then burnt in the combustion chamber 110, forming the working medium 113. From there, the working medium 113 flows along the hot-gas passage 111 past the guide vanes 130 and the rotor blades 120. The working medium 113 is expanded at the rotor blades 120, transferring its momentum, so that the rotor blades 120 drive the rotor 103 and the latter in turn drives the generator coupled to it.

While the gas turbine 100 is operating, the components which are exposed to the hot working medium 113 are subject to thermal stresses. The guide vanes 130 and rotor blades 120 of the first turbine stage 112, as seen in the direction of flow of the working medium 113, together with the heat shield elements which line the annular combustion chamber 110, are subject to the highest thermal stresses.

To be able to withstand the temperatures which prevail there, they may be cooled by means of a coolant.

Substrates of the components may likewise have a directional structure, i.e. they are in single-crystal form (SX structure) or have only longitudinally oriented grains (DS structure).

By way of example, iron-based, nickel-based or cobalt-based superalloys are used as material for the components, in particular for the turbine blade or vane 120, 130 and components of the combustion chamber 110.

Superalloys of this type are known, for example, from EP 1 204 776 B1, EP 1 306 454, EP 1 319 729 A1, WO 99/67435 or WO 00/44949; these documents form part of the disclosure with regard to the chemical composition of the alloys.

The blades or vanes 120, 130 may likewise have coatings protecting against corrosion (MCrAlX; M is at least one element selected from the group consisting of iron (Fe), cobalt (Co), nickel (Ni), X is an active element and stands for yttrium (Y) and/or silicon, scandium (Sc) and/or at least one rare earth element, or hafnium). Alloys of this type are known from EP 0 486 489 B1, EP 0 786 017 B1, EP 0 412 397 B1 or EP 1 306 454 A1; these documents are intended to form part of this disclosure with regard to the chemical composition.

It is also possible for a thermal partially stabilized or fully stabilized by yttrium oxide and/or calcium oxide and/or magnesium oxide, to be present on the MCrAlX.barrier coating, which consists for example of ZrO₂, Y₂O₃-ZrO₂, i.e. unstabilized, Columnar grains are produced in the thermal barrier coating by suitable coating processes, such as for example electron beam physical vapor deposition (EB-PVD).

The guide vane 130 has a guide vane root (not shown here), which faces the inner housing 138 of the turbine 108, and a guide vane head which is at the opposite end from the guide vane root. The guide vane head faces the rotor 103 and is fixed to a securing ring 140 of the stator 143.

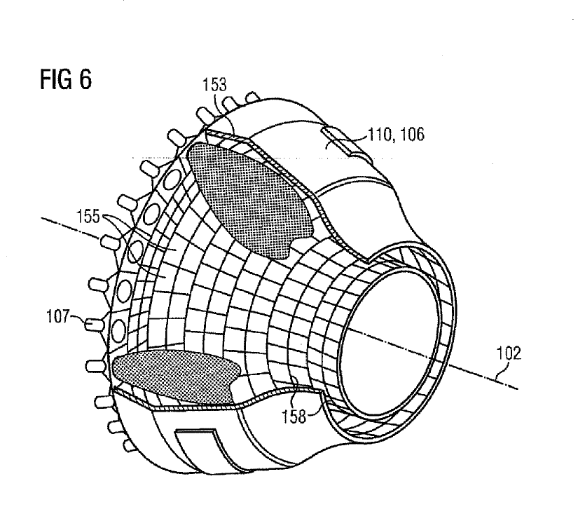

FIG. 6 shows a combustion chamber 110 of a gas turbine.

The combustion chamber 110 is configured, for example, as what is known as an annular combustion chamber, in which a multiplicity of burners 107, which generate flames 156, arranged circumferentially around an axis of rotation 102 open out into a common combustion chamber space 154. For this purpose, the combustion chamber 110 overall is of annular configuration positioned around the axis of rotation 102.

To achieve a relatively high efficiency, the combustion chamber 110 is designed for a relatively high temperature of the working medium M of approximately 1000° C. to 1600° C. To allow a relatively long service life even with these operating parameters, which are unfavorable for the materials, the combustion chamber wall 153 is provided, on its side which faces the working medium M, with an inner lining formed from heat shield elements 155.

On the working medium side, each heat shield element 155 made from an alloy is equipped with a particularly heat-resistant protective layer (MCrAlX layer and/or ceramic coating) or is made from material that is able to withstand high temperatures (solid ceramic bricks).

These protective layers may be similar to the turbine blades or vanes, i.e. for example MCrAlX: M is at least one element selected from the group consisting of iron (Fe), cobalt (Co), nickel (Ni), X is an active element and stands for yttrium (Y) and/or silicon and/or at least one rare earth element or hafnium (Hf). Alloys of this type are known from EP 0 486 489 B1, EP 0 786 017 B1, EP 0 412 397 B1 or EP 1 306 454 A1; these documents are intended to form part of this disclosure with regard to the chemical composition of the alloy.

It is also possible for a, for example, ceramic thermal barrier coating to be present on the MCrAlX, consisting for example of ZrO₂, Y₂O₃-ZrO₂, i.e. unstabilized, partially stabilized or fully stabilized by yttrium oxide and/or calcium oxide and/or magnesium oxide.

Columnar grains are produced in the thermal barrier coating by suitable coating processes, such as for example electron beam physical vapor deposition (EB-PVD).

Other coating processes are possible, e.g. atmospheric plasma spraying (APS), LPPS, VPS or CVD. The thermal barrier coating may include grains that are porous or have micro-cracks or macro-cracks, in order to improve the resistance to thermal shocks.

Refurbishment means that after they have been used, protective layers may have to be removed from heat shield elements 155 (e.g. by sand-blasting). Then, the corrosion and/or oxidation layers and products are removed. If appropriate, cracks in the heat shield element 155 are also repaired. This is followed by recoating of the heat shield elements 155, after which the heat shield elements 155 can be reused.

Moreover, a cooling system may be provided for the heat shield elements 155 and/or their holding elements, on account of the high temperatures in the interior of the combustion chambe 110. The heat shield elements 155 are then, for example, hollow and may also have cooling holes (not shown) opening out into the combustion chamber space 154.

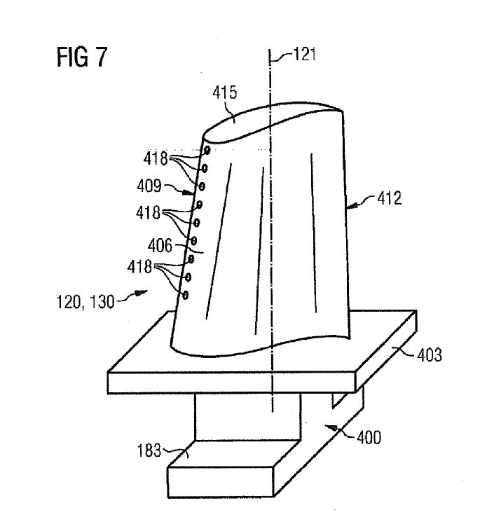

FIG. 7 shows a perspective view of a rotor blade 120 or guide vane 130 of a turbomachine, which extends along a longitudinal axis 121.

The turbomachine may be a gas turbine of an aircraft or of a power plant for generating electricity, a steam turbine or a compressor.

The blade or vane 120, 130 has, in succession along the longitudinal axis 121, a securing region 400, an adjoining blade or vane platform 403 and a main blade or vane part 406 and a blade or vane tip 415.

As a guide vane 130, the vane 130 may have a further platform (not shown) at its vane tip 415.

A blade or vane root 183, which is used to secure the rotor blades 120, 130 to a shaft or a disk (not shown), is formed in the securing region 400.

The blade or vane root 183 is designed, for example, in hammerhead form. Other configurations, such as a fir-tree or dovetail root, are possible.

The blade or vane 120, 130 has a leading edge 409 and a trailing edge 412 for a medium which flows past the main blade or vane part 406.

In the case of conventional blades or vanes 120, 130, by way of example solid metallic materials, in particular superalloys, are used in all regions 400, 403, 406 of the blade or vane 120, 130.

Superalloys of this type are known, for example, from EP 1 204 776 B1, EP 1 306 454, EP 1 319 729 A1, WO 99/67435 or WO 00/44949; these documents form part of the disclosure with regard to the chemical composition of the alloy.

The blade or vane 120, 130 may in this case be produced by a casting process, by means of directional solidification, by a forging process, by a milling process or combinations thereof.

Workpieces with a single-crystal structure or structures are used as components for machines which, in operation, are exposed to high mechanical, thermal and/or chemical stresses.

Single-crystal workpieces of this type are produced, for example, by directional solidification from the melt. This involves casting processes in which the liquid metallic alloy solidifies to form the single-crystal structure, i.e. the single-crystal workpiece, or solidifies directionally.

In this case, dendritic crystals are oriented along the direction of heat flow and form either a columnar crystalline grain structure (i.e. grains which run over the entire length of the workpiece and are referred to here, in accordance with the language customarily used, as directionally solidified) or a single-crystal structure, i.e. the entire workpiece consists of one single crystal. In these processes, a transition to globular (polycrystalline) solidification needs to be avoided, since non-directional growth inevitably forms transverse and longitudinal grain boundaries, which negate the favorable properties of the directionally solidified or single-crystal component.

Where the text refers in general ten is to directionally solidified microstructures, this is to be understood as meaning both single crystals, which do not have any grain boundaries or at most have small-angle grain boundaries, and columnar crystal structures, which do have grain boundaries running in the longitudinal direction but do not have any transverse grain boundaries. This second form of crystalline structures is also described as directionally solidified microstructures (directionally solidified structures).

Processes of this type are known from U.S. Pat. No. 6,024,792 and EP 0 892 090 A1; these documents form part of the disclosure with regard to the solidification process.

The blades or vanes 120, 130 may likewise have coatings protecting against corrosion or oxidation e.g. (MCrAlX; M is at least one element selected from the group consisting of iron (Fe), cobalt (Co), nickel (Ni), X is an active element and stands for yttrium (Y) and/or silicon and/or at least one rare earth element, or hafnium (Hf)). Alloys of this type are known from EP 0 486 489 B1, EP 0 786 017 B1, EP 0 412 397 B1 or EP 1 306 454 A1; these documents are intended to form part of this disclosure with regard to the chemical composition of the alloy.

The density is preferably 95% of the theoretical density.

A protective aluminum oxide layer (TGO=thermally grown oxide layer) is formed on the MCrAlX layer (as an intermediate layer or as the outermost layer).

The layer preferably has a composition Co-30Ni-28Cr-8Al-0.6Y-0.7Si or Co-28Ni-24Cr-10Al-0.6Y. In addition to these cobalt- based protective coatings, it is also preferable to use nickel-based protective layers, such as Ni-10Cr-12Al-0.6Y-3Re or Ni-12Co-21Cr-11Al-0.4Y-2Re or Ni-25Co-17Cr-10Al-0.4Y-1.5Re.

It is also possible for a thermal barrier coating, which is preferably the outermost layer and consists for example of ZrO₂, Y₂O₃-ZrO₂, i.e. unstabilized, partially stabilized or fully stabilized by yttrium oxide and/or calcium oxide and/or magnesium oxide, to be present on the MCrAlX.

The thermal barrier coating covers the entire MCrAlX layer.

Columnar grains are produced in the thermal barrier coating by suitable coating processes, such as for example electron beam physical vapor deposition (EB-PVD).

Other coating processes are possible, for example atmospheric plasma spraying (APS), LPPS, VPS or CVD. The thermal barrier coating may include grains that are porous or have micro-cracks or macro-cracks, in order to improve the resistance to thermal shocks. The thermal barrier coating is therefore preferably more porous than the MCrAlX layer.

Refurbishment means that after they have been used, protective layers may have to be removed from components 120, 130 (e.g. by sand-blasting). Then, the corrosion and/or oxidation layers and products are removed. If appropriate, cracks in the component 120, 130 are also repaired. This is followed by recoating of the component 120, 130, after which the component 120, 130 can be reused.

The blade or vane 120, 130 may be hollow or solid in form. If the blade or vane 120, 130 is to be cooled, it is hollow and may also have film-cooling holes 418 (indicated by dashed lines).

1.-19. (canceled)

20. A burner element, comprising:
a surface which may come into contact with a fuel,
wherein the surface includes an aluminum oxide-containing coating,
wherein the aluminum oxide-containing coating comprises α-Al₂O₃, and
wherein the aluminum oxide-containing coating is an aluminum oxide first layer.

21. The burner element as claimed in claim 20,
wherein the aluminum oxide-containing coating comprises an aluminum-rich second layer and the aluminum oxide-containing first layer, and
wherein the aluminum oxide-containing first layer is arranged above the second layer.

22. The burner element as claimed in claim 20, wherein the aluminum oxide-containing coating includes a layer thickness of 50 μm to 100 μm.

23. The burner element as claimed in claim 21, wherein the aluminum oxide-containing coating includes the layer thickness of 50 μm to 100 μm.

24. The burner element as claimed in claim 20, wherein the burner element comprises steel as a base material.

25. The burner element as claimed in claim 24, wherein the burner element comprises 16Mo3 steel as the base material.

26. The burner element as claimed in claim 20, wherein the burner element is a fuel feed line or a fuel distributor.

27. A burner, comprising:
a burner element, comprising:
a surface which may come into contact with a fuel,
wherein the surface includes an aluminum oxide-containing coating,
wherein the aluminum oxide-containing coating comprises α-Al₂O₃, and
wherein the aluminum oxide-containing coating is an aluminum oxide first layer.

28. The burner as claimed in claim 27, wherein the burner is a pilot burner.

29. A process for coating a surface of a burner element which may come into contact with a fuel, comprising:
coating the surface with an aluminum oxide-comprising layer.

30. The process as claimed in claim 29, wherein aluminum oxide is applied to the surface by chemical vapor deposition.

31. The process as claimed in claim 30, wherein the surface is enriched with aluminum at a temperature between 1000° C. and 1100° C. within the scope of the chemical vapor deposition.

32. The process as claimed in claim 31, wherein the surface is enriched with aluminum at a temperature of 1050° C.

33. The process as claimed in claim 30, wherein the surface is enriched with aluminum over a period of time of between 3 and 5 hours within the scope of the chemical vapor deposition.

34. The process as claimed in claim 31, wherein the surface is enriched with aluminum over the period of time of 4 hours.

35. The process as claimed in claim 30, wherein the surface is aged at a temperature between 800° C. and 900° C., after it has been enriched with aluminum, within the scope of the chemical vapor deposition.

36. The process as claimed in claim 35, wherein the surface is aged at a temperature of 850° C.

37. The process as claimed in claim 30, wherein the surface is aged over a period of time of between 1 and 3 hours, after it has been enriched with aluminum, within the scope of the chemical vapor deposition.

38. The process as claimed in claim 35, wherein the surface is aged over a period of time of 2 hours.

39. The process as claimed in claim 29, wherein the aluminum oxide-comprising layer includes a thickness of 50 μm to 100 μm.
